(19) United States
(12) Patent Application Publication
(10) Pub. No.: US 2007/0228876 A1
(43) Pub. Date: Oct. 4, 2007

(54) Diamond Frequency Control Devices and Associated Methods

(76) Inventor: Chien-Min Sung, Taipei County (TW)

Correspondence Address: THORPE NORTH & WESTERN, LLP., 8180 SOUTH 700 EAST, SUITE 350, SANDY, UT, 84070, US

(21) Appl. No.: 11/278,197

(22) Filed: Mar. 31, 2006

(51) Int. Cl. H01L 41/00

(52) U.S. Cl. 310/320

(57) ABSTRACT

Various frequency control devices and their methods of use are provided. In one aspect, a bulk acoustic wave (BAW) device may include a diamond layer disposed between piezoelectric layers, and a pair of electrodes coupled to the piezoelectric layers. In such a configuration, the pair of electrodes may be configured such that an electrical signal introduced across the pair of electrodes can generate an acoustic wave in the diamond layer as a result of movement in the piezoelectric layers. The pair of electrodes may be a pair of electrode layers, and the diamond layer and the two piezoelectric layers may be disposed at least partially therebetween.

### FIELD OF THE INVENTION

The present invention relates to frequency control devices incorporating super-hard materials, such as diamond or diamond-like substances, and methods for making such devices. Accordingly, the present invention involves the fields of chemistry, materials science, and physics.

### BACKGROUND OF THE INVENTION

Frequency control components are fundamental to the function of many electronic devices, particularly in the realm of wireless networks such as pagers, cell phones, satellite communication, navigation systems, etc. These and other electronic systems often require frequency control components that function beyond 6 GHz. As more electronic devices begin to crowd the higher frequencies, the need for narrow front-end filters that reduce adjacent channel interference and output filters that limit transmitter bandwidth is increased. Additionally, such crowding increases the need for frequency control components that can function at even higher frequency ranges.

Another trend affecting frequency control components is the miniaturization of electronic architecture due to the decreasing size of many electronic devices. As the size of such devices decrease, direct integration of frequency filters and resonators onto integrated circuits becomes increasingly important. As such, the configurations of resonators and filters may require alterations in design in order for them to reside on integrated circuits.

Surface acoustic wave (SAW) devices are examples of filters that have been utilized to improve upper frequency ranges and sharpness of tuning in many electronics and telecommunications applications. These devices usually comprise a piezoelectric layer having at least two electrodes disposed on the surface. The surface is generally very smooth in order to maximize the frequency control characteristics of the device. An electric field introduced across the electrodes can generate an acoustic wave such that acoustic propagation is perpendicular to the plane of the electric field. Because these acoustic waves generally travel along the surface of the piezoelectric layer, the high frequency characteristics of such devices may be limited due to the limits of acoustic propagation.

Bulk acoustic wave (BAW) devices such as film bulk acoustic wave resonators (FBAR) have also been utilized to increase upper frequency ranges and tuning sharpness. These devices often comprise a piezoelectric layer sandwiched between two electrode layers. An electrical field applied across these electrodes results in the formation of an acoustic wave in the device. The acoustic wave propagates parallel to the plane of the electric field through the body of the piezoelectric material. This body wave can travel at a higher velocity than a surface wave, thus increasing the resonant frequency potential of these devices as compared to SAW devices. Resonance within FBAR devices is given by the acoustic wave velocity and the thickness of the piezoelectric layer. Because primarily resonant frequencies pass though the filter, such devices have become useful narrow band-pass filters.

Various factors limit the high frequency characteristics of FBAR devices, however. The frequency of the resonance is limited by the thickness and physical characteristics of the piezoelectric material. The velocity of the acoustic wave is limited by the maximum propagation speed of the wave in the piezoelectric material, hence the resonant frequency is similarly limited. Additionally, FBAR filters generate heat through use that may build up within the electronic device, thus causing thermally induced failures and other heat related issues.

As such, frequency control devices and methods for making such devices which have improved high frequency performance continue to be sought.

### SUMMARY OF THE INVENTION

Accordingly, various embodiments of the present invention provide frequency control devices and methods for their use. In one aspect, a bulk acoustic wave (BAW) device may include a diamond layer disposed between piezoelectric layers, and a pair of electrodes coupled to the piezoelectric layers. In such a configuration, the pair of electrodes may be configured such that an electrical signal introduced across the pair of electrodes can generate an acoustic wave in the diamond layer as a result of movement in the piezoelectric layers. The pair of electrodes may be a pair of electrode layers, and the diamond layer and the two piezoelectric layers may be disposed at least partially therebetween.

Various materials are contemplated that may be of use in embodiments of the present invention. For example, the diamond layer may be a material such as single-crystal diamond, polycrystalline diamond, diamond-like carbon, amorphous diamond, and combinations thereof. Additionally, the piezoelectric layer may be any piezoelectric material known to one skilled in the art, such as SiO₂, Si₃N₄, Al₂O₃, AlN, GaAs, GaP, LiTaO₃, LiNbO₃, ZnO, Pb(Zr, Ti)O₃, Ta₂O₅, Nb₂O₅, BeO, L₂B₄O₇, KNbO₃, ZnS, ZnSe, CdS, and mixtures thereof.

The BAW device may further include a heat spreader layer thermally coupled to at least one of the pair of electrode layers. In one aspect, the heat spreader layer may be a diamond heat spreader layer. Additionally, an intermediate layer may be disposed between the diamond layer and at least one of the piezoelectric layers. Though the intermediate layer may be any useful material known to one skilled in the art, in various aspects it may be AlN, CrN, Si, SiC, SiN, WC, GaN, BN, diamond-like carbon, W, Mo, Cr, and composites or alloys thereof.

Methods of making BAW devices are also provided by the various embodiments of the present invention. In one aspect, a method of making a BAW device having improved high frequency characteristics may include disposing a diamond layer between piezoelectric layers and functionally coupling an electrode to each of the piezoelectric layers. In such a configuration, an electrical signal introduced across the electrodes may generate an acoustic wave in the diamond layer as a result of movement in the piezoelectric layers.

In another aspect, a method of making a BAW device may further include providing a substrate, disposing a first electrode layer on the substrate, and disposing on the first electrode layer a diamond layer between piezoelectric layers. The method may further include thermally coupling a heat spreader layer on the substrate prior to disposing the first electrode layer. The heat spreader layer may be any thermally conductive material known to one skilled in the art, including diamond, diamond-like carbon, copper, aluminum, etc.

In one detailed aspect, disposing the diamond layer between two piezoelectric layers may comprise disposing a first piezoelectric layer on the first electrode layer, disposing the diamond layer on the first piezoelectric layer, and disposing a second piezoelectric layer on the diamond layer. In such a configuration, the diamond layer is located between the first and second piezoelectric layers.

The substrate can be any material useful in the construction of such a filtering device. For example, and without limitation, the substrate may include tungsten, silicon, silicon carbide, silicon nitride, titanium carbide, titanium nitride, boron nitride, graphite, ceramics, glass, molybdenum, zirconium, tantalum, chromium, aluminum nitride, diamond, and composites thereof. In one aspect the substrate may be a diamond layer.

There has thus been outlined, rather broadly, the more important features of the invention so that the detailed description thereof that follows may be better understood, and so that the present contribution to the art may be better appreciated. Other features of the present invention will become clearer from the following detailed description of the invention, taken with the accompanying drawings and claims, or may be learned by the practice of the invention.

### BRIEF DESCRIPTION OF THE DRAWINGS

FIG. 1 is a cross-sectional view of a diamond frequency control device in accordance with an embodiment of the present invention.

FIG. 2 is a cross-sectional view of another diamond frequency control device in accordance with an embodiment of the present invention.

FIG. 3 is a cross-sectional view of yet another diamond frequency control device in accordance with an embodiment of the present invention.

FIG. 4 is a cross-sectional view of a further diamond frequency control device in accordance with an embodiment of the present invention.

The above figures are provided for illustrative purposes only. It should be noted that actual dimensions of layers and features may differ from those shown.

### DETAILED DESCRIPTION

Before the present invention is disclosed and described, it is to be understood that this invention is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

It must be noted that, as used in this specification and the appended claims, the singular forms “a,” and, “the” include plural referents unless the context clearly dictates otherwise. Thus, for example, reference to “a diamond layer” includes one or more of such layers, reference to “a carbon source” includes reference to one or more of such carbon sources, and reference to “a CVD technique” includes reference to one or more of such CVD techniques.

### Definitions

In describing and claiming the present invention, the following terminology will be used in accordance with the definitions set forth below.

As used herein, “frequency control device” refers to any device that limits frequency input or frequency output. Non-limiting examples of such devices include both frequency filters and frequency resonators.

As used herein, “bulk acoustic wave” refers to an acoustic wave propagating through or having the potential to propagate through a material in a direction that is parallel to the plane of the electric field responsible for generating the acoustic wave.

As used herein, “substrate” refers to a surface to which various materials can be joined in forming a frequency control device. The substrate may be any shape, thickness, or material, required in order to achieve a specific result, and includes, but is not limited to, metals, alloys, ceramics, diamond, and mixtures thereof. Further, in some aspects, the substrate, may be an existing semiconductor device or wafer, or may be a material which is capable of being joined to a suitable device.

As used herein, “growth substrate” refers to a surface upon which a material is deposited through vapor deposition, sputtering, high-pressure high-temperature processes, etc. As such, “growth surface” refers to the surface of the growth substrate upon which the deposition occurs. The growth substrate can be a temporary substrate, or it can be permanently integrated into a frequency control device. Growth substrates may include substrates as defined above, electrode layers, piezoelectric layers, heat sink layers, diamond layers, etc.

As used herein, “coupled” refers to at least two materials or structures brought into such close proximity as to permit mutual influence. Such influence may be electrical, structural, thermal, etc. Specifically, “thermally coupled” refers to at least two materials or structures that exert thermal influence on one another.

As used herein, “metallic” refers to any type of material or compound wherein the majority portion of the material is a metal. As such, various oxide, nitride, and carbide compounds, as well as any other material or compound containing a greater non-metal portion than metal portion are considered to be “non-metallic.” Examples of various metals considered to be particularly useful in the practice of the present invention include, without limitation: aluminum, tungsten, molybdenum, tantalum, zirconium, vanadium, chromium, copper, and alloys thereof.

As used herein, “ceramic” refers to a non-diamond, non-metallic, material, which is hard, heat resistant, corrosion resistant, and can be polished to have a surface roughness (Ra) of less than about 1 micrometer. Further, as used herein, “ceramic” materials may contain at least one element selected from the group consisting of: Al, Si, Li, Zn, and Ga. Oxides, nitrides, and various other compounds which include the above recited elements are well known as ceramics to those skilled in the art. Additional materials considered to be “ceramics” as used herein, such as glass, are known to those skilled in the art. Examples of specific ceramics useful in the present invention include without limitation, Si, SiO₂, Si₃N₄, Al₂O₃, AlN, BN, TiN, ZrN, GaAs, GaP, LiTaO₃, LiNbO₃, ZnO, glass, such as soda glass, etc.

As used herein, “nucleation enhancer” refers to a material, which increases the quality of a diamond layer formed from a plurality of diamond nuclei using a CVD process. In one aspect, the nucleation enhancer may increase the quality of the diamond layer by reducing movement or, or immobilizing diamond nuclei. Examples of nucleation enhancers include without limitation, metals, and various metallic compounds, as well as carbides and carbide forming materials.

As used herein with respect to a nucleation enhancer layer and an intermediate layer, “thin” refers to the thickness or depth of the layer being sufficiently small so as to not substantially interfere with the functionality of the frequency control device. In one aspect, the thickness of the nucleation enhancer may be less than about 0.1 micrometers. In another aspect, the thickness may be less than 10 nanometers. In another aspect, the thickness may be less than about 5 nanometers.

As used herein, “diamond layer” refers to any structure, regardless of shape, which contains diamond-containing materials which can be incorporated into a frequency control device. Thus, for example, a diamond film partially or entirely covering a surface is included within the meaning of these terms. Additionally, a layer of a material, such as metals, acrylics, or composites, having diamond particles disbursed therein is included in these terms.

As used herein, “diamond-containing materials” refer to any of a number of materials which include carbon atoms bonded with at least a portion of the carbons bonded in at least some sp³ bonding. Diamond-containing materials can include, but are not limited to, natural or synthetic diamond, polycrystalline diamond, diamond-like carbon, amorphous diamond, and the like.

As used herein, “diamond-like carbon” refers to a carbonaceous material having carbon atoms as the majority element, with a substantial amount of such carbon atoms bonded in distorted tetrahedral coordination. Diamond-like carbon (DLC) can typically be formed by PVD processes, although CVD or other processes could be used such as vapor deposition processes. Notably, a variety of other elements can be included in the DLC material as either impurities, or as dopants, including without limitation, hydrogen, sulfur, phosphorous, boron, nitrogen, silicon, tungsten, etc.

As used herein, “amorphous diamond” refers to a type of diamond-like carbon having carbon atoms as the majority element, with a substantial amount of such carbon atoms bonded in distorted tetrahedral coordination. In one aspect, the amount of carbon in the amorphous diamond can be at least about 90%, with at least about 20% of such carbon being bonded in distorted tetrahedral coordination. Amorphous diamond also has a higher atomic density than that of diamond (176 atoms/cm³). Further, amorphous diamond and diamond materials contract upon melting.

As used herein, “vapor deposited” refers to materials which are formed using vapor deposition techniques.

As used herein, “vapor deposition” refers to a process of depositing materials on a substrate through the vapor phase. Vapor deposition processes can include any process such as, but not limited to, chemical vapor deposition (CVD) and physical vapor deposition (PVD). A wide variety of variations of each vapor deposition method can be performed by those skilled in the art. Examples of vapor deposition methods include hot filament CVD, rf-CVD, laser CVD (LCVD), laser ablation, conformal diamond coating processes, metal-organic CVD (MOCVD), sputtering, thermal evaporation PVD, ionized metal PVD (IMPVD), electron beam PVD (EBPVD), reactive PVD, and the like.

As used herein, “chemical vapor deposition,” or “CVD” refers to any method of chemically depositing diamond or other particles in a vapor form upon a surface. Various CVD techniques are well known in the art.

As used herein, “CVD passive material” refers to a material which does not allow substantial deposition of diamond or other materials using CVD methods directly to the material. One example of a CVD passive material with respect to deposition of diamond is copper. As such, during CVD processes carbon will not deposit on the copper but only on CVD active materials such as silicon, diamond, or other known materials. Thus, CVD passive materials can be “passive” with respect to some materials and not others. For example, a number of carbide formers can be successfully deposited onto copper.

As used herein, “nucleation side,” “nucleation surface,” and similar terms may be used interchangeably, and refer to the side or surface of a diamond layer at which nucleation of diamond particles originated. Otherwise described, the nucleation surface of a diamond layer is the side or surface, which was first deposited upon the growth surface of the growth substrate.

As used herein, “Ra” refers to a measure of the roughness of a surface as determined by the difference in height between a peak and a neighboring valley. Further, “Rmax” is a measure of surface roughness as determined by the difference in height between the highest peak on the surface and the lowest valley on the surface.

As used herein with respect to an identified property or circumstance, “substantially” refers to a degree of deviation that is sufficiently small so as to not measurably detract from the identified property or circumstance. The exact degree of deviation allowable may depend on the specific context.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc.

This same principle applies to ranges reciting only one numerical value. Furthermore, such an interpretation should apply regardless of the breadth of the range or the characteristics being described.

### The Invention

Diamond materials may prove to be very valuable when incorporated into various frequency control components, such as bulk acoustic wave (BAW) devices. In such frequency control devices, a piezoelectric layer is often disposed between two electrodes. This layer converts electrical energy into mechanical energy and vice versa. If supplied with a mixed-frequency signal, only a resonant frequency of the frequency control device will pass. A resonance condition occurs in the piezoelectric layer if its thickness is equal to an integer multiple of half the wavelength of a signal. The fundamental resonance frequency is thus inversely proportional to the thickness of the piezoelectric material used, and is equal to the acoustic velocity of the acoustic wave in the material divided by two times its thickness. Because of the high atomic density of diamond materials, propagation of acoustic waves occurs at very high velocities. As such, resonant frequencies of devices utilizing diamond layers to propagate acoustic waves may exhibit higher frequency control characteristics. The higher acoustic velocities increase resonance and thus allow filters and resonators to function at much higher frequencies. Such increases in frequency control may be particularly useful in wireless networks, communications, and cell phone systems.

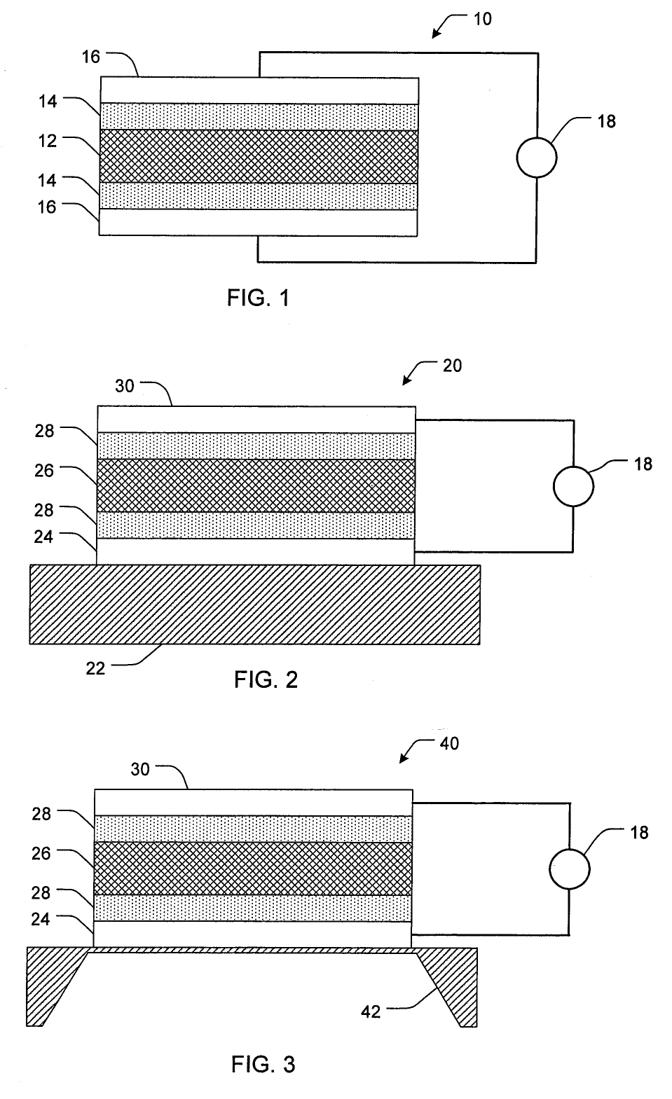

Referring now to FIG. 1, a BAW device 10 according to one aspect of the present invention is shown. Such a device may include a diamond layer 12 disposed between piezoelectric layers 14 and a pair of electrodes 16, where the electrodes 16 are coupled to the piezoelectric 14 layers. The pair of electrodes 16 may be configured such that an electrical signal introduced across them generates an acoustic wave in the diamond layer 12 as a result of movement in the piezoelectric layers 14. An electrical signal generating device 18 introduces the electrical signal across the pair of electrodes 16. In many situations, the introduction of an electrical signal across the pair of electrodes 16 can improve the quality of the signal due to the improved filtering characteristics of devices according to aspects of the present invention.

The present invention also contemplates methods of making the frequency control devices disclosed herein. In one aspect, a method of making a bulk acoustic wave device having improved high frequency characteristics is provided. The method may include disposing a diamond layer between piezoelectric layers and functionally coupling an electrode to each of the piezoelectric layers, such that an electrical signal introduced across the electrodes generates an acoustic wave in the diamond layer as a result of movement in the piezoelectric layers.

Diamond and diamond-like substances have many properties, such as high acoustic propagation velocity, high thermal conductivity, and high electrical resistivity, which make them useful for incorporation into various frequency control devices. As such, any diamond or diamond-like substance can be utilized in embodiments of the present invention, including, without limitation, single-crystal diamond, polycrystalline diamond, diamond-like carbon, amorphous diamond, nanodiamond, and combinations thereof. In one specific aspect, the diamond layer may be a diamond-like carbon layer. In another aspect, the diamond layer may be constructed of a layer of single-crystal or near single-crystal diamond. In yet another aspect, the diamond layer may be constructed of nanodiamond. The thickness of the diamond layer will vary depending on the tuning and intended application of the frequency control device. As such, there may be significant variation in the thicknesses of these layers. As an example, however, in one aspect the diamond layer may have a thickness of from about 1 μm to about 1000 μm. In another aspect, the diamond layer may have a thickness of from about 5 μm to about 500 μm. In yet another aspect, the diamond layer may have a thickness of from about 10 μm to about 100 μm.

Numerous methods of producing diamond layers are known to those skilled in the art, all of which are considered to be within the scope of the present invention. For example, methods for incorporating diamond or diamond-like materials into a frequency control device can include processes such as vapor deposition techniques, sputtering, high-pressure high-temperature growth, adhesive bonding, brazing, etc.

Any number of known vapor deposition techniques may be used to form the diamond layer. The most common vapor deposition techniques include chemical vapor deposition (CVD) and physical vapor deposition (PVD), although any similar method can be used if similar properties and results are obtained. In one aspect, CVD techniques such as hot filament, microwave plasma, oxyacetylene flame, rf-CVD, laser CVD (LCVD), metal-organic CVD (MOCVD), laser ablation, conformal diamond coating processes, and direct current arc techniques may be utilized. Typical CVD techniques use gas reactants to deposit the diamond or diamond-like material in a layer, or film. These gases generally include a small amount (i.e. less than about 5%) of a carbonaceous material, such as methane, diluted in hydrogen. A variety of specific CVD processes, including equipment and conditions, are well known to those skilled in the art.

As an example, in forming a layer of diamond or diamond-like material on a growth substrate using CVD techniques, a plurality of diamond grains, or “seeds,” may be first placed upon the growth surface of the growth substrate. The placement of such seeds may be accomplished using CVD itself such as by applying a voltage bias, by polishing with micron-sized diamond, or by other methods known in the art.

These seeds act as diamond nuclei and facilitate the growth of a diamond layer outwardly from the growth surface as carbon vapor is deposited thereon. It should be noted that the growth substrate can be a layer of piezoelectric material or other growth substrate as described herein. A nucleation enhancing layer can be formed on the growth surface in order to improve the quality and deposition time of the diamond layer. Specifically, the diamond layer can be formed by depositing applicable nuclei, such as diamond nuclei, on the growth surface of a growth substrate, and then growing the nuclei into a film or layer using a vapor deposition technique. While ceramics and other non-metal materials are able to achieve a smooth growth surface, many of these materials, such as oxides, are unable to nucleate diamond and retain it in place very well. Therefore, in order to overcome such a deficiency, in one aspect of the present invention, a thin nucleation enhancer layer can be coated upon the growth surface of the growth substrate. Diamond nuclei are then placed upon the nucleation enhancer layer, and the growth of the diamond layer proceeds via CVD as described herein.

A variety of suitable materials will be recognized by those in skilled in the art which can serve as a nucleation enhancer. In one aspect of the present invention, the nucleation enhancer may be a material selected from the group consisting of metals, metal alloys, metal compounds, carbides, carbide formers, and mixtures thereof. Examples of carbide forming materials include without limitation, tungsten (W), tantalum (Ta), titanium (Ti), zirconium (Zr), chromium (Cr), molybdenum (Mo), silicon (Si), and manganese (Mn). Additionally, examples of carbides include tungsten carbide (WC), silicon carbide (SiC), titanium carbide (TiC), zirconium carbide (ZrC), and mixtures thereof among others.

The nucleation enhancer layer, when used, is a layer which is thin enough that it does not to adversely affect the functionality of the frequency control device. In one aspect, the thickness of the nucleation enhancer layer may be less than about 0.1 micrometers. In another aspect, the thickness may be less than about 10 nanometers. In yet another aspect, the thickness of the nucleation enhancer layer is less than about nanometers. In a further aspect of the invention, the thickness of the nucleation enhancer layer is less than about 3 nanometers.

Polishing the growth surface with a diamond powder or paste is especially useful when an ultra-smooth surface is desired. Further, when a fine diamond paste is used, many diamond particles may become embedded in the growth surface, and can serve as seeds for increased nucleation rates. Additionally, certain metals, such as iron, nickel, cobalt, and their alloys, are known to catalyze diamond into amorphous carbon or graphite at high temperatures (i.e. greater than 700° C.). Thus, by limiting the amount of such substance in the composition of the growth substrate, the amount of diamond which will be catalyzed to graphite is greatly reduced, and the overall quality of the growth surface may be increased.

In one more detailed aspect of the present invention, the growth surface of the growth substrate can be etched with micro-scratches to enhance nucleation. One method of introducing such micro-scratches is to immerse the growth substrate in an acetone bath containing suspended micron-size diamond particles. Ultrasonic energy can then be applied to the growth substrate and/or the fluid. Upon removal of the growth substrate from the ultrasonic bath, a portion of the micron-sized diamonds remains on the growth surface as diamond growth seeds.

In another detailed aspect of the present invention, nucleation can be optionally enhanced by applying an electrical current such that a strong negative bias is created at the growth substrate. For example, an applied voltage of about 120 volts can increase nucleation density up to a million fold.

In yet another detailed aspect of the present invention, nucleation rates can be increased by controlling the composition of the growth surface of the growth substrate such as by ion implantation of C, Si, Cr, Mn, Ti, V, Zr, W, Mo, Ta, and the like by PVD or PECVD. PVD processes are typically at lower temperatures than CVD processes and in some cases can be below about 200° C. such as about 150° C. Other methods of increasing diamond nucleation will be readily apparent to those skilled in the art.

Different degrees of quality may be achieved during the vapor deposition process, as required by the particular device being fabricated. Those of ordinary skill in the art will readily recognized the differing conditions and techniques which produce a given degree of quality, and will be able to achieve various degrees of quality without undue experimentation. Accordingly, various methods may be employed to increase the quality of the diamond layer which is created by vapor deposition techniques. For example, diamond particle quality can be increased by reducing the methane flow rate, and increasing the total gas pressure during the early phase of diamond deposition. Such measures, decrease the decomposition rate of carbon, and increase the concentration of hydrogen atoms. Thus a significantly higher percentage of the carbon will be deposited in a sp³ bonding configuration, and the quality of the diamond nuclei formed is increased. Additionally, the nucleation rate of diamond particles deposited on the growth surface of the growth substrate or the nucleation enhancer layer may be increased in order to reduce the amount of interstitial space between diamond particles.

In yet another aspect of the present invention, one low temperature vapor deposition process can be a conformal diamond coating process. Conformal diamond coating processes can provide a number of advantages over conventional diamond film processes. Conformal diamond coating can be performed on a wide variety of substrates, including non-planar substrates. A growth surface can be pretreated under diamond growth conditions in the absence of a bias to form a carbon film. The diamond growth conditions can be conditions which are conventional CVD deposition conditions for diamond without an applied bias. As a result, a thin carbon film can be formed which is typically less than about 100 angstroms. The pretreatment step can be performed at almost any growth temperature such as from about 200° C. to about 900° C., although lower temperatures below about 500° C. may be preferred. Without being bound to any particular theory, the thin carbon film appears to form within a short time, e.g., less than one hour, and is a hydrogen terminated amorphous carbon.

The carbon film can be seeded with nanodiamond using ultrasonic agitation of a dispersion of nanodiamond powder to form a seeded substrate. The dispersion can generally be a dispersion of nanodiamond in methanol although any suitable dispersion can be used. Excess nanodiamond can be removed by washing. Seeding in this manner can achieve very high nucleation densities, e.g. exceeding 10¹¹/cm².

The seeded substrate can be subjected to diamond growth conditions to form the diamond film as a conformal diamond film. The diamond growth conditions can be those conditions which are commonly used in traditional CVD diamond growth. However, unlike conventional diamond film growth, the diamond film produced using the above pretreatment steps results in a conformal diamond film. Further, the diamond film typically begins growth substantially over the entire substrate with substantially no incubation time. In addition, a continuous film, e.g. substantially no grain boundaries, can develop within about 80 nm of growth.

Although suitable conditions can vary, process temperatures can be held below about 500° C. with good results. For example, temperatures from about 250° C. to about 500° C. can be useful and from about 300° C. to about 450° C. may generally be preferred. Growth conditions do not need to be the same as those used during the pretreatment step and can vary substantially therefrom. For example, conventional CVD diamond growth conditions can be used in the pretreatment step to form the thin carbon film, while plasma or laser ablation conditions can be used during the growth step.

In addition to vapor deposition processes, various high temperature configurations are contemplated to produce a layer of diamond or diamond-like material that would be suitable for the various aspects of the present invention. In one aspect, diamond cubes can be arranged into a layer and fused together through a high-temperature high-pressure process. Further discussion of such a process of producing a layer of diamond can be found in U.S. patent application Ser. No. 11/200,647, filed on Aug. 9, 2005, which is hereby incorporated by reference. Following the construction of the diamond layer, piezoelectric layers may then be affixed thereto.

An additional consideration includes the surface roughness of the diamond layer. The transmission of the acoustic wave from the piezoelectric layers to the diamond layer may be facilitated by a very smooth interface therebetween. Such a smooth interface between the layers may increase mechanical coupling between the layers, and thus decrease impedance. Rough regions between the layers may introduce distortions in the acoustic wave generated in the diamond layer. As such, surface roughness of the diamond layer may be minimized in order to increase the frequency characteristics of the various devices of the present invention. Naturally the degree of acceptable roughness may vary, depending on the intended applications of such devices. It is considered to be within the knowledge of one of ordinary skill in the art to be able to determine an acceptable roughness range for a particular application given the desired frequency range. Also, in certain aspects of the present invention, increased roughness of the diamond layer and/or the piezoelectric layers may actually facilitate bonding, and thus be desirable in certain circumstances.

Turning to piezoelectric layers, thickness and physical characteristics of the materials making up the layers may play an important role in the frequency characteristics of the frequency control device. As has been discussed, the resonant frequency of the device is related, in part, to the thickness of the sandwich of piezoelectric and diamond layers. The resonant frequency is also dependent on the velocity of the acoustic wave through this sandwich layer. As such, the thicknesses of the piezoelectric layers, as well as the material from which they are constructed, may have an impact on the frequency control characteristics of the device. It is considered to be well within the knowledge of one skilled in the art, once in possession of the various aspects of the present invention, to be able to select piezoelectric materials and construct a sandwich of layers of a particular thickness in order to precisely tune a frequency control device. Accordingly, in one aspect the materials of the piezoelectric layers may include, without limitation, SiO₂, Si₃N₄, Al₂O₃, AlN, GaAs, GaP, LiTaO₃, LiNbO₃, ZnO, Pb(Zr, Ti)O₃, Ta₂O₅, Nb₂O₅, BeO, L₂B₄O₇, KNbO₃, ZnS, ZnSe, CdS, and mixtures thereof. In a specific aspect, the piezoelectric layer may include an AlN layer.

As has been described, specific thicknesses of the piezoelectric layers may vary depending on the tuning and intended application of the frequency control device. As such, there may be significant variation in the thicknesses of these layers. As a non-limiting example, however, in one aspect a piezoelectric layer may have a thickness of from about 100 nm to about 10 μm. In another aspect, a piezoelectric layer may have a thickness of from about 500 nm to about 5 μm. In yet another aspect, a piezoelectric layer may have a thickness of from about 800 nm to about 3 μm. It should be understood, however, that these thicknesses should be in no way limiting. BAW device are contemplated that range from very simple to very complex, and thus such complexity would be reflected in the piezoelectric layers.

Various methods of disposing the diamond layer between two piezoelectric layers are contemplated. In one aspect, such a method may include disposing a first piezoelectric layer on a first electrode layer, disposing the diamond layer on the first piezoelectric layer, and disposing a second piezoelectric layer on the diamond layer, such that the diamond layer is located between the first and second piezoelectric layers. As such, the first piezoelectric layer can be deposited on the electrode layer by any means known, including various vapor deposition techniques, sputtering, etc. A preformed piezoelectric layer may also be affixed to the electrode layer by adhesive bonding, brazing, etc. Also, the diamond layer can be deposited onto the first piezoelectric layer as has been described herein. Alternatively, a preformed diamond layer may be affixed to the first piezoelectric layer by adhesive bonding or brazing. The second piezoelectric layer can also be deposited on or affixed to the diamond layer through the utilization of any of the various techniques described herein.

In another aspect, piezoelectric layers can be disposed on two sides of a free-standing diamond layer. Regardless of the order in which the layers are assembled, various manufacturing techniques are available for applying a piezoelectric layer onto a diamond layer. For example, in one aspect, disposing at least one of the first and second piezoelectric layers onto the diamond layer may be accomplished by deposition from a vapor phase using a CVD or a PVD process. In another aspect, disposing at least one of the first and second piezoelectric layers may be accomplished by bonding a piezoelectric material to the diamond layer using a bonding material.

Though various methods of bonding the layers of the present invention together are contemplated, such bonding can occur by using an ultra thin layer of bonding material. Prior to bonding, corresponding adjoining surfaces may be polished or prepared to have a comparable surface roughness. The surface roughness will depend on the intended final device. Subsequently, an ultra thin layer of bonding material may be produced by forming a layer of bonding material on either of the surfaces to be joined and then pressing the two surfaces together in order to reduce the bonding layer thickness to less than about 1 micron and preferably less than about 10 nanometers (i.e. only a few molecules thick). The bonding material may comprise an organic binder such as an epoxy or may be a reactive metal such as Ti, Si, Zr, Cr, Mo, W, Mn, or mixtures thereof. In the case of a reactive metal, the metal may be sputtered on either surface and then pressed against the other surface under heat and vacuum conditions. At these ultra thin thicknesses, the bonding material is more stable at higher temperatures. For example, typical epoxy binders will fail at temperatures above about 200° C.; however at ultra thin thicknesses the epoxy remains strong at higher temperatures.

Electrodes can be utilized in various configurations depending on the intended application of the frequency control device. In one aspect, the diamond layer and the piezoelectric layers may be disposed at least partially between a pair of electrode layers. Additionally, in those frequency control devices employing at least two electrodes, each electrode may be of the same configuration or different. They may each be the same or different in size, thickness, material, etc. Also, the electrodes can be of any material known to one skilled in the art that can conduct electrical energy and thus cause movement in the piezoelectric layers. In one aspect, the electrode can be metallic. Suitable metallic materials include, without limitation, copper, aluminum, nickel, alloys thereof, and the like.

Intermediate layers can be utilized in order to improve the performance and/or durability of the frequency control device. For example, an intermediate layer can be disposed between the diamond layer and at least one of the piezoelectric layers. Without wishing to be bound to any particular theory, such a layer may increase the adhesion between the piezoelectric materials and the diamond. Intermediate layers may also increase the conduction of the acoustic wave across the interface between the layers. By utilizing such means to decrease the mechanical/acoustic impedance between these layers, the acoustic velocity of the wave may increase, thus increasing the frequency characteristics of the device. Though numerous materials are contemplated, the intermediate layer can include, without limitation, AlN, CrN, Si, SiC, SiN, WC, GaN, BN, diamond-like carbon, W, Mo, Cr, and composites or alloys thereof. In one specific aspect, the intermediate layer may include BN. In another specific aspect, the BN can be wurtzitic BN.

Various aspects of the present invention may also include substrates which can provide support and/or other functional properties to the device. Substrates can be a permanent addition to the frequency control device or a temporary support to be removed after manufacturing and/or installation. Turning to FIG. 2, one method of making a frequency control device 20 including a substrate layer may include providing a substrate 22, disposing a first electrode layer on the substrate 22 and disposing a sandwich of a diamond layer 26 between piezoelectric layers 28 on the first electrode layer 24. A second electrode layer 30 may be disposed on a piezoelectric layer 28 opposite to the first electrode layer 24.

The substrate can be made from any number of materials. Typically, the substrate can be formed of a material having desirable properties for a particular application. For example, in some embodiments, mechanical strength, thermal expansion, thermal conductivity, electrical resistivity, and the like can be important. Several non-limiting examples of suitable substrate materials include tungsten, silicon, silicon carbide, silicon nitride, titanium carbide, titanium nitride, boron nitride, graphite, ceramics, glass, molybdenum, zirconium, tantalum, chromium, aluminum nitride, manganese, diamond-like carbon, diamond, and composites thereof. However, in one aspect, the substrate may be made of, or substantially made of, a metallic material. The metallic material may be a member selected from the group consisting of aluminum, copper, tungsten, molybdenum, tantalum, zirconium, vanadium, and chromium. In another embodiment, the substrate may be made of, or made substantially of, non-metals, such as carbides and ceramics, including glass, oxide, and nitride materials. Examples of carbide materials include without limitation, tungsten carbide (WC), silicon carbide (SiC), titanium carbide (TiC), zirconium carbide (ZrC), and mixtures thereof among others. Examples of oxide materials include without limitation, quartz (i.e. crystalline SiO₂), corundum or sapphire (i.e. Al₂O₃), LiTaO₃, LiNbO₃, ZnO, and mixtures thereof. Examples of nitride materials include without limitation, silicon nitride (Si₃N₄), aluminum nitride (AlN), boron nitride (BN), titanium nitride (TiN), zirconium nitride (ZrN), and mixtures thereof, among others. Examples of glass include all types of glass including soda glass, etc.

A substrate comprising tungsten can provide exceptional mechanical support as well as low thermal expansion. Also, a substrate comprising diamond can also provide exceptional mechanical support and low thermal expansion. Similarly, a substrate comprising silicon can be highly compatible with incorporation into various semiconductor devices and/or products. In one specific aspect, the substrate may be a layer of diamond. Also, the substrate can comprise a material suitable for use as a semiconductor. It may also be beneficial for the substrate to include a material having a thermal expansion which is comparable to that of diamond in order to prevent damage to the diamond layer upon cooling from the brazing temperatures.

The substrate can be joined to an electrode layer by a variety of methods. In one aspect, an electrode layer can be bonded to the substrate with a bonding material as has been described herein. In another aspect, the substrate can be joined to an electrode by brazing. A variety of brazing alloys may be suitable for use in the present invention. Of particular benefit are braze alloys which include a carbide former such as Ti, Cr, Si, Zr, Mn, and mixtures thereof. Several exemplary braze alloys include those of Ag—Cu—Ti, Ag—Cu—Sn—Ti, Ni—Cr—B—Si, Ni—Cu—Zr—Ti, Cu—Mn, and mixtures thereof. The brazing alloy may be supplied in any known form such as a powder or as a thin foil. Typical brazing temperatures are below about 1000° C. such as about 900° C.

The functionality of various frequency control devices according to aspects of the present invention may be facilitated when both sides are free to vibrate. As such, these devices can be tuned to a particular frequency bandwidth by removing a portion of the substrate. FIG. 3 illustrates a tuned frequency control device 40 according to one aspect of the present invention. In this case, material has been removed from the substrate layer 42 in order to tune the device to a particular frequency bandwidth and allow vibration of the side facing the substrate 42. Such tuning is within the ability of one skilled in the art.

Given the high frequencies at which many of these devices function, heat buildup may often become a critical factor to their functionality. As such, heat spreader layers can be utilized to channel and dissipate heat. In one aspect a heat spreader layer can be thermally coupled to at least one of the pair of electrode layers in the frequency control device in order to dissipate this heat. The heat spreader can be in a variety of configurations and can be thermally coupled to either of the pair of electrodes. In one aspect, however, the heat spreader layer can be disposed on the substrate prior to disposing the first electrode layer. Such a heat spreader would draw heat from the first electrode layer and channel it between that electrode and the substrate. Though various materials are known to effectively channel and dissipate heat, specific examples include metals, metallic materials, diamond, etc. In one aspect, the heat spreader layer may include a diamond material. Diamond can effectively be utilized as such due to its high thermal conductivity. The diamond material can be thermally coupled to either of the pair of electrodes as described. In one specific aspect, however, the diamond layer between the piezoelectric layers may function as a heat spreader layer. As such, merely thermally coupling this diamond layer to an exterior heat spreader layer or surface would function to channel and dissipate heat away from the frequency control device.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A bulk acoustic wave device, comprising:
a diamond layer disposed between piezoelectric layers; and
a pair of electrodes coupled to the piezoelectric layers, the pair of electrodes configured such that an electrical signal introduced across the pair of electrodes generates an acoustic wave in the diamond layer as a result of movement in the piezoelectric layers.

2. The device of claim 1, wherein the pair of electrodes is a pair of electrode layers.

3. The device of claim 2, wherein the diamond layer and the two piezoelectric layers are disposed at least partially between the pair of electrode layers.

4. The device of claim 1, wherein the diamond layer is a material selected from the group consisting of single-crystal diamond, polycrystalline diamond, diamond-like carbon, amorphous diamond, and combinations thereof.

5. The device of claim 4, wherein the diamond layer is a diamond-like carbon layer.

6. The device of claim 1, wherein the piezoelectric layer is a material selected from the group consisting of SiO₂, Si₃N₄, Al₂O₃, AlN, GaAs, GaP, LiTaO₃, LiNbO₃, ZnO, Pb(Zr, Ti)O₃, Ta₂O₅, Nb₂O₅, BeO, L₂B₄O₇, KNbO₃, ZnS, ZnSe, CdS, and mixtures thereof.

7. The device of claim 6, wherein the piezoelectric layer is an AlN layer.

8. The device of claim 3, further comprising a heat spreader layer thermally coupled to at least one of the pair of electrode layers.

9. The device of claim 8, wherein the heat spreader layer is a diamond heat spreader layer.

10. The device of claim 1, further comprising an intermediate layer between the diamond layer and at least one of the piezoelectric layers.

11. The device of claim 10, wherein the intermediate layer is a material selected from the group consisting of AlN, CrN, Si, SiC, SiN, WC, GaN, BN, diamond-like carbon, W, Mo, Cr, and composites or alloys thereof.

12. The device of claim 11, wherein the intermediate layer is BN.

13. The device of claim 12, wherein the BN is wurtzitic BN.

14. The device of claim 13, wherein the bulk acoustic wave device is configured to be incorporated into a telecommunications device.

15. The device of claim 13, wherein the bulk acoustic resonator is configured to be incorporated into a mobile phone.

16. The device of claim 1, wherein the diamond layer has a thickness of from about 1 μm to about 1000 μm.

17. The device of claim 1, wherein the diamond layer has a thickness of from about 5 μm to about 500 μm.

18. The device of claim 1, wherein the diamond layer has a thickness of from about 10 μm to about 100 μm.

19. A method for improving the quality of an electronic signal, comprising applying an electronic signal across the pair of electrodes of the device of claim 1.

20. A method of making a bulk acoustic wave device having improved high frequency characteristics, comprising:
disposing a diamond layer between piezoelectric layers; and
functionally coupling an electrode to each of the piezoelectric layers, such that an electrical signal introduced across the electrodes generates an acoustic wave in the diamond layer as a result of movement in the piezoelectric layers.

21. The method of claim 20, wherein at least one electrode is a layer.

22. The method of claim 21, wherein the diamond layer and the piezoelectric layers are located between electrode layers.

23. The method of claim 21, further comprising:
providing a substrate;
disposing a first electrode layer on the substrate; and
disposing the diamond layer between piezoelectric layers on the first electrode layer.

24. The method of claim 23, further comprising disposing a heat spreader layer on the substrate prior to disposing the first electrode layer.

25. The method of claim 24, wherein the heat spreader layer is a diamond heat spreader layer.

26. The method of claim 23, wherein the substrate comprises a member selected from the group consisting of tungsten, silicon, silicon carbide, silicon nitride, titanium carbide, titanium nitride, boron nitride, graphite, ceramics, glass, molybdenum, zirconium, tantalum, chromium, aluminum nitride, diamond, and composites thereof.

27. The method of claim 26, wherein the substrate is a diamond layer.

28. The method of claim 23, further including removing a portion of the substrate to tune the device.

29. The method of claim 23, wherein disposing the diamond layer between two piezoelectric layers further comprises:
disposing a first piezoelectric layer on the first electrode layer;
disposing the diamond layer on the first piezoelectric layer; and
disposing a second piezoelectric layer on the diamond layer, such that the diamond layer is located between the first and second piezoelectric layers.

30. The method of claim 29, wherein disposing at least one of the first and second piezoelectric layers is accomplished by deposition from a vapor phase using a CVD or PVD process.

31. The method of claim 29, wherein disposing at least one of the first and second piezoelectric layers is accomplished by bonding a piezoelectric material using either an organic binder or a reactive bonding layer.
